(19) United States
(12) Patent Application Publication
(10) Pub. No.: US 2016/0240747 A1
(43) Pub. Date: Aug. 18, 2016

(54) OPTOELECTRONIC COMPONENT AND METHOD OF PRODUCTION THEREOF

(71) Applicant: OSRAM Opto Semiconductors GmbH, Regensburg (DE)

(72) Inventors: Markus Pindl, Tegernheim (DE); Martin Brandl, Kelheim (DE)

(21) Appl. No.: 15/027,482

(22) PCT Filed: Oct. 14, 2014
(86) PCT No.: PCT/EP2014/072042

§ 371 Date: Apr. 6, 2016

(30) Foreign Application Priority Data
Oct. 16, 2013 (DE) 10 2013 220 960.6

(51) Int. Cl. H01L 33/50; H01L 33/00; H01L 33/58; H01L 33/48; H01L 33/56

(52) U.S. Cl. CPC H01L 33/502; H01L 33/486; H01L 33/56; H01L 33/58; H01L 33/0095; H01L 2933/0083; H01L 2933/005; H01L 2933/0041; H01L 2933/0033; H01L 2933/0058

(57) ABSTRACT

An optoelectronic component includes a housing body, wherein a cavity is formed on the upper side of the housing body, and a channel extending from the cavity to an outer edge of the upper side of the housing body is formed on the upper side of the housing body; and a method of producing an optoelectronic component including providing a flat panel of a multiplicity of housing bodies, each housing body having a cavity opening onto an upper side of the panel wherein the cavities of neighboring housing bodies connect by channels and open onto the upper side of the panel, arranging an encapsulation material in the cavities of the housing bodies, and dividing the panel.

### TECHNICAL FIELD

This disclosure relates to an optoelectronic component and a method of producing an optoelectronic component.

### BACKGROUND

Optoelectronic components in which an optoelectronic semiconductor chip, for example, a light-emitting diode chip (LED chip) is arranged in a cavity of a housing, are known. The cavity is filled with an encapsulation material in which the optoelectronic semiconductor chip is embedded. During production of such optoelectronic components, cavities of a continuous panel of a multiplicity of housings are simultaneously filled with encapsulation material. The encapsulation may, for example, be carried out by compression molding. The encapsulation material is thus distributed beyond the edges of the cavities, between the housings of the panel. To this end, a sufficient space, which is likewise filled with the encapsulation material, must be provided over the edges of the cavities of the housing. That part of the encapsulation material remaining over the housings of the optoelectronic components increases material costs, leads to a reduction in efficiency and makes it more difficult to divide the optoelectronic components.

### SUMMARY

We provide an optoelectronic component including a housing body, wherein a cavity is formed on an upper side of the housing body, and a channel extending from the cavity to an outer edge of the upper side of the housing body is formed on the upper side of the housing body.

We also provide a method of producing an optoelectronic component including providing a flat panel of a multiplicity of housing bodies, each housing body having a cavity opening onto an upper side of the panel, wherein the cavities of neighboring housing bodies connect by channels and open onto the upper side of the panel, arranging an encapsulation material in the cavities of the housing bodies, and dividing the panel.

### BRIEF DESCRIPTION OF THE DRAWINGS

FIG. 1 shows a plan view of a panel of a multiplicity of housing bodies.

FIG. 2 shows a section through the panel.

FIG. 3 shows a plan view of an optoelectronic component.

FIG. 4 shows a section through the optoelectronic component.

### LIST OF REFERENCES

100 panel
101 upper side
110 separating plane
200 housing body
201 upper side
202 outer edge
210 cavity
211 bottom region
220 channel
300 lead frame
301 upper side
302 lower side
400 encapsulation material
410 volume section
420 cover layer
421 thickness
430 optical lens
500 optoelectronic semiconductor chip
501 upper side
502 lower side
510 bonding wire
600 optoelectronic component
610 housing

### DETAILED DESCRIPTION

Our optoelectronic component comprises a housing body on the upper side of which a cavity is formed. Furthermore, a channel extending from the cavity to an outer edge of the upper side of the housing body is formed on the upper side of the housing body. Advantageously, the cavity of the housing body of the optoelectronic component may be filled with an encapsulation material through the channel during the production of the optoelectronic component.

In the optoelectronic component, an optoelectronic semiconductor chip may be arranged on a bottom region of the cavity. The optoelectronic semiconductor chip may, for example, be a light-emitting diode chip (LED chip). The cavity of the housing of the optoelectronic component may form a reflector for the electromagnetic radiation emitted by the optoelectronic semiconductor chip of the optoelectronic component, and collimate this radiation. Arrangement of the optoelectronic semiconductor chip on the bottom region of the cavity of the housing advantageously protects the optoelectronic semiconductor chip against damage by external mechanical effects.

An encapsulation material may be arranged in the cavity and the channel. Advantageously, the encapsulation material can enter the cavity through the channel during production of the optoelectronic component so that the optoelectronic component can advantageously be produced particularly simply. The encapsulation material arranged in the cavity may advantageously be used as additional protection for an optoelectronic semiconductor chip arranged in the cavity and embedded in the encapsulation material.

The encapsulation material may comprise silicone. In this way, the encapsulation material is advantageously economically obtainable and simple to process. Furthermore, the encapsulation material may be configured to be optically essentially transparent for electromagnetic radiation emitted by an optoelectronic semiconductor chip of the optoelectronic component.

The encapsulation material may comprise embedded wavelength-converting particles. The wavelength-converting particles embedded in the encapsulation material may be provided to convert a wavelength of electromagnetic radiation emitted by an optoelectronic semiconductor chip of the optoelectronic component. To this end, the wavelength-converting particles may be configured to absorb electromagnetic radiation with a first wavelength and subsequently emit electromagnetic radiation with a second, typically longer, wavelength. The wavelength-converting particles may, for example, comprise an organic or inorganic luminescent material. The wavelength-converting particles may also comprise quantum dots.

The encapsulation material may extend over the upper side of the housing body and form a layer there. Advantageously, the layer can likewise contribute to filling the cavity with the encapsulation material during production of the optoelectronic component.

A section arranged over the housing body of the layer may have a thickness of less than 100 μm, preferably a thickness of less than 50 μm. Advantageously, only a very small part of electromagnetic radiation emitted by an optoelectronic semiconductor chip of the optoelectronic component is lost in a layer with such a small thickness. Furthermore, only a very small amount of encapsulation material is required to form such a thin layer.

The optoelectronic component may comprise an optical lens arranged over the cavity. The optical lens may, for example, be configured as a converging lens or as a diverging lens. The optical lens may advantageously be used to shape a light beam emitted by the optoelectronic component.

The lens may be integrally formed with the encapsulation material. In this way, the lens can advantageously be produced particularly simply and economically. In particular, it is possible to form the lens simultaneously with filling the cavity of the housing body of the optoelectronic component with the encapsulation material.

A method of producing an optoelectronic component has steps of providing a flat panel of a multiplicity of housing bodies, each housing body having a cavity opening onto an upper side of the panel, the cavities of neighboring housing bodies being connected by channels opening onto the upper side of the panel, arranging an encapsulation material in the cavities of the housing bodies, and dividing the panel. Advantageously, this method allows parallel production of a multiplicity of optoelectronic components so that low production costs per optoelectronic component are achieved. During arrangement of the encapsulation material in the cavities of the housing bodies, the encapsulation material may advantageously enter the cavities of the housing bodies through the channels. A space arranged over the upper side of the panel for distribution of the encapsulation material can advantageously be configured to be particularly small so that the method is advantageously associated with minimal consumption of encapsulation material. Furthermore, in the optoelectronic components which can be obtained by the method, only a thin layer of encapsulation material is therefore formed over the upper side of the housing bodies so that brightness losses due to this layer are small.

The method may comprise a further step, carried out before arrangement of the encapsulation material, of arranging an optoelectronic semiconductor chip on a bottom region of the cavity of a housing body. Advantageously, the optoelectronic semiconductor chip in the cavity of the housing body is embedded in the encapsulation material so that the optoelectronic semiconductor chip is protected against subsequent damage by external mechanical effects.

The encapsulation material may flow at least partially through the channels during arrangement of the encapsulation material. Advantageously, the encapsulation material can enter the cavities of the plurality of housing bodies in a simple way so that reliable filling of all the cavities can be ensured.

The encapsulation material may be arranged by compression molding in the cavities. Advantageously, this allows the method to be carried out economically.

Provision of the flat panel may comprise forming the panel by injection molding. Advantageously, this allows economical production of the flat panel of the multiplicity of housing bodies.

Division of the panel may be carried out along separating planes oriented perpendicularly to the channels. In this way, it is advantageously necessary to divide only short sections of the encapsulation material during division of the panel so that the division can be carried out in a simple one-stage process.

The above-described properties, features and advantages, as well as the way in which they are achieved, will become more clearly and comprehensively understandable in connection with the following description of examples, which will be explained in more detail in connection with the drawings.

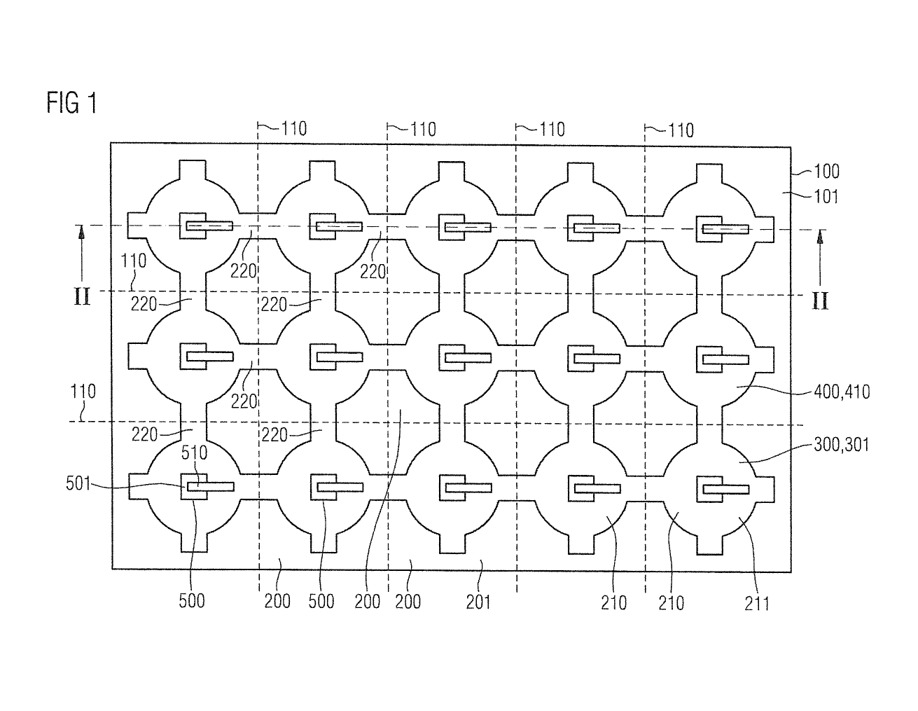

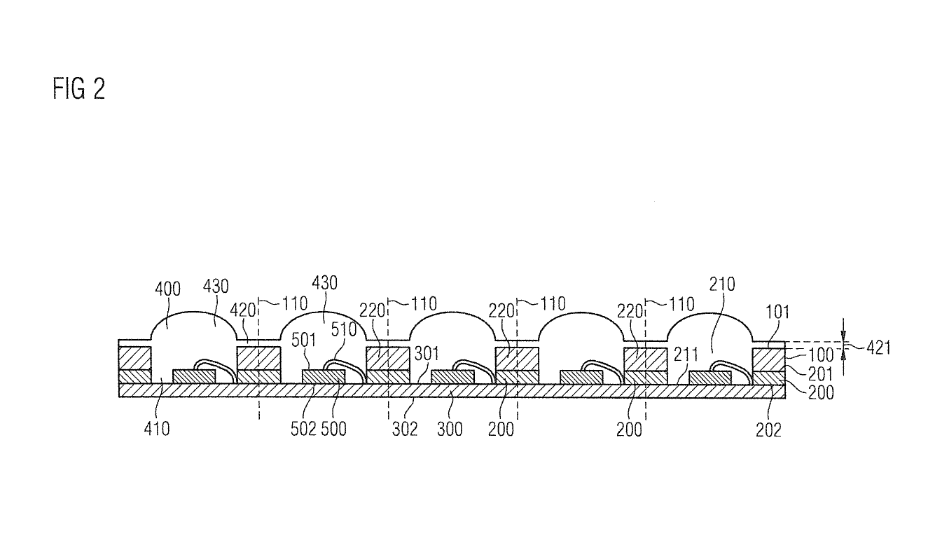

FIG. 1 shows a schematic plan view of a panel 100 of housing bodies 200. FIG. 2 shows a schematic sectional side view of the panel 100.

The panel 100 comprises a multiplicity of the housing bodies 200. The housing bodies 200 are arranged in a regular arrangement in the panel 100 and are connected to one another. In the example represented in the figures, the panel 100 comprises an array of 3×5 housing bodies 200. The panel 100 could, however, also comprise a substantially larger number of housing bodies 200.

The housing bodies 200 are arranged an upper side 301 of a lead frame 300 represented only schematically in the figures. The lead frame 300 comprises an electrically conductive material, for example, a metal. The lead frame 300 is configured as a substantially flat plate with the upper side 301 and a lower side 302 opposite the upper side 301. In the lateral direction, the lead frame 300 may have structuring with openings, formed between the upper side 301 and the lower side 302, which subdivides the lead frame 300 in the lateral direction into sections electrically insulated from one another.

The connected housing bodies 200 of the panel 100 comprise an electrically insulating material, for example, a plastic material. The housing bodies 200 may, for example, comprise an epoxide. The housing bodies 200 may, for example, have been formed by injection molding on the upper side 301 of the lead frame 300.

The connected housing bodies 200 of the panel 100 comprise an upper side 201 facing away from the upper side 301 of the lead frame 300. The upper sides 201 of the connected housing bodies 200 of the panel 100 together form an upper side 201 of the panel 100.

Each housing body 200 of the panel 100 has a cavity 210 opening onto the upper side 201 of the respective housing body 200. The cavity 210 extends from the upper side 201 of the housing body 200 into the housing body 200 as far as the upper side 301 of the lead frame 300. The upper side 301 of the lead frame 300 therefore forms a bottom region 211 of the cavity 210. In the lateral direction of the panel 100, the cavities 210 may, for example, have rectangular or, as represented, discoid cross-sectional surfaces. The walls of the cavity 210 extending between the bottom region 211 of a cavity 210 and the upper side 201 of the respective housing body 200 may, as represented, be perpendicularly oriented. The cavities 210 could, however, for example, also widen from the bottom region 211 toward the upper side 201.

The cavities 210 of neighboring housing bodies 200 of the panel 100 respectively connect to one another by channels 220. The channels 220 extend from the upper sides 201 of the housing bodies 200 into the housing bodies 200, but while preferably not reaching the upper side 301 of the lead frame 300. Bottom regions of the channels 220 are preferably formed by the material of the connected housing bodies 200 of the panel 100. The channels 220 preferably extend in a straight line on the shortest path between the cavities 210 of neighboring housing bodies 200. Perpendicularly to its longitudinal extent direction oriented from one cavity 210 to the next cavity 210, each channel 220 has a width preferably much less than the lateral diameter of the cavities 210.

In the example represented in FIGS. 1 and 2, the housing bodies 200 of the panel 100 are arranged in a regular rectangular arrangement of rows and columns. The channels 220 extend both row-wise and column-wise between the cavities 210 of housing bodies 200 neighboring one another. In this way, for each housing body 200 of the panel 100 except for housing bodies 200 arranged on an outer edge of the panel 100, the cavity 210 connects via four channels 220 to the cavities 210 of four neighboring housing bodies 200. It is, however, also possible to omit some of the channels 220 and arrange channels 220, for example, only column-wise or only row-wise. It would likewise be possible to provide additional diagonal channels 220 connecting to one another the cavities 210 of housing bodies 200 neighboring at their corner. It is likewise possible to arrange the housing bodies 200 of the panel 100 in an arrangement other than a rectangular arrangement. In this case as well, the cavities 210 of the housing bodies 200 connect to one another via channels 220.

The cavities 210 and the channels 220 of the housing bodies 200 are preferably already formed during production of the panel 100 of housing bodies 200. This may, for example, be done by injection molding using a suitable mold during production of the panel 100 of housing bodies 200.

An optoelectronic semiconductor chip 500 is respectively arranged on the bottom region 211 of the cavity 210 of each housing body 200. The optoelectronic semiconductor chips 500 may, for example, be light-emitting diode chips (LED chips). Each optoelectronic semiconductor chip 500 has an upper side 501 and a lower side 502 opposite the upper side 501. Each optoelectronic semiconductor chip 500 is configured to generate electromagnetic radiation, for example, visible light and emit this on its upper side 501. Each optoelectronic semiconductor chip 500 is arranged on the bottom region 211 of a cavity 210 of a housing body 200 such that the lower side 502 of the optoelectronic semiconductor chip 500 faces toward the bottom region 211 of the cavity 210. In this case, the lower side 502 of the optoelectronic semiconductor chip 500 may, for example, connect by an electrically conductive connecting medium, for instance a solder or an electrically conductive adhesive, to the upper side 301 of a section of the lead frame 300.

In each optoelectronic semiconductor chip 500, a first electrical contact pad is formed on the upper side 501. A second electrical contact pad of the optoelectronic semiconductor chip 500 may, for example, be formed on the lower side 502 of the optoelectronic semiconductor chip 500. In each optoelectronic semiconductor chip 500, an electrical voltage may be applied to the optoelectronic semiconductor chip 500 between the first electrical contact pad and the second electrical contact pad to make the optoelectronic semiconductor chip 500 emit electromagnetic radiation. In each optoelectronic semiconductor chip 500, the first electrical contact pad formed on the upper side 501 electrically conductively connects by a bonding wire 510 to a section of the lead frame 300. The bonding wire 510 preferably extends entirely inside the cavity 210 of the respective housing body 200. The second electrical contact pad, arranged on the lower side 502, may in each optoelectronic semiconductor chip 500 electrically conductively connect to a section of the lead frame 300, for example, by the electrically conductive connecting medium between the optoelectronic semiconductor chip 500 and the upper side 301 of the lead frame 300.

The arrangement of the optoelectronic semiconductor chips 500 in the cavities 210 of the housing bodies 200 of the panel 100 is preferably carried out after the formation of the housing bodies 200 of the panel 100. Application of the bonding wires 510 is then carried out.

The cavities 210 of the housing bodies 200 of the panel 100 are filled with an encapsulation material 400. The channels 220 are also filled with the encapsulation material 400. The optoelectronic semiconductor chips 500 arranged in the cavities 210 of the housing bodies 200 of the panel 100 and the bonding wires 510 connected to the optoelectronic semiconductor chip 500 are embedded in the encapsulation material 400. In this way, the encapsulation material 400 protects the optoelectronic semiconductor chips 500 and the bonding wires 510 against damage by external mechanical effects, as well as against ingress of dirt and moisture.

The encapsulation material 400 comprises a material essentially optically transparent for electromagnetic radiation emitted by the optoelectronic semiconductor chips 500. For example, the encapsulation material 400 may comprise silicone. The encapsulation material 400 may furthermore comprise embedded wavelength-converting particles intended to convert a wavelength of electromagnetic radiation emitted by the optoelectronic semiconductor chips 500. To this end, the wavelength-converting particles embedded in the encapsulation material 400 may be configured to absorb electromagnetic radiation with a first wavelength and subsequently emit electromagnetic radiation with a second, typically longer, wavelength. In this way, the wavelength converting particles embedded in the encapsulation material 400 may, for example, be configured to convert blue light generated by the optoelectronic semiconductor chips 500 into white light. The wavelength-converting particles embedded in the encapsulation material 400 may, for example, comprise an organic luminescent material or inorganic luminescent material. The wavelength-converting particles may also comprise quantum dots.

The encapsulation material 400 preferably fills the cavities 210 of the housing bodies 200 of the panel 100 fully. In each cavity 210, a volume section 410 of the encapsulation material 400, in which the optoelectronic semiconductor chip 500 and the bonding wire 510 are embedded, is arranged.

In addition, the encapsulation material 400 also extends over the upper sides 201 of the housing bodies 200 of the panel 100. A part of the encapsulation material 400, arranged over the upper sides 201 of the housing bodies 200 of the panel 100, forms a cover layer 420. The cover layer 420 therefore connects the volume sections 410 of the encapsulation material 400 arranged in the cavities 210 of neighboring housing bodies 200 of the panel 100. In addition, the volume sections 410 of the encapsulation material 400 arranged in the cavities 210 of neighboring housing bodies 200 connect to one another by parts of the encapsulation material 400 arranged in the channels 220.

The cover layer 420 of the encapsulation material 400 arranged above the upper sides 201 of the housing bodies 200 of the panel 100 has a thickness 421 in a direction perpendicular to the upper sides 201 of the housing bodies 200. Preferably, the thickness 421 of the cover layer 420 is less than 100 μm. Particularly preferably, the cover layer 420 has a thickness 421 of less than 50 μm.

An optical lens 430 is arranged over the cavity 210 of each housing body 200 of the panel 100. The optical lens 430 is arranged above the cover layer 420 of the encapsulation material 400 and preferably consists of the encapsulation material 400. The optical lenses 430 may be formed during introduction of the encapsulation material 400 into the cavities 210 of the housing bodies 200 of the panel 100. The optical lenses 430 are preferably configured as converging lenses, although they may also be configured as diverging lenses or in a different manner. The optical lenses 430 may be used for beam shaping of the electromagnetic radiation emitted by the optoelectronic semiconductor chips 500. For example, the optical lenses 430 may be used for collimation of the electromagnetic radiation emitted by the optoelectronic semiconductor chips 500.

Introduction of the encapsulation material 400 into the cavities 210 of the housing bodies 200 of the panel 100 may, for example, be carried out by compression molding. In this case, the encapsulation material 400 may be distributed via the channels 220 between the cavities 210 of the individual housing bodies 200 of the panel 100. The encapsulation material 400 in this case flows through the channels 220. To a lesser extent, the encapsulation material 400 may also be distributed via the cover layer 420 over the upper sides 201 of the housing bodies 200 of the panel 100. The channels 220 ensure that the cavities 210 of all the housing bodies 200 of the panel 100 are fully filled by the encapsulation material 400.

After the cavities 210 of the housing bodies 200 of the panel 100 have been filled with the encapsulation material 400, the housing bodies 200 may be separated from one another by dividing the panel 100. To this end, the panel 100 is separated along separating planes 110. The separating planes 110 extend between the housing bodies 200. In the rectangular arrangement of the housing bodies 200 as represented in FIGS. 1 and 2, the separating planes 110 extend between the rows and columns of the housing bodies 200. The separating planes 110 pass through the channels 220 of the housing bodies 200 of the panel 100. In this case, the channels 220 are cut by the separating planes 110 perpendicularly to their longitudinal direction oriented from one cavity 210 to the next cavity 210.

The division of the panel 100 may, for example, be carried out by a sawing process. In this case, the saw cuts extend essentially through the material of the housing bodies 200 of the panel 100 and only in the region of the narrow channels 220 and in the region of the cover layer 420 through the encapsulation material 400. This can make it possible to ignore a hardness difference between the material of the housing bodies 200 and the encapsulation material 400, and to carry out division of the panel 100 along the separating planes 110 in a one-stage sawing process. This possibility is reinforced in particular by the small thickness 421 of the cover layer 420 arranged over the upper sides 201 of the housing bodies 200 of the encapsulation material 400. Division of the panel 100 may, however, also be carried out, for example, in a two-stage sawing process in which the cover layer 420 of the encapsulation material 400 is divided in one stage and the housing bodies 200 of the panel 100 are divided in a further stage.

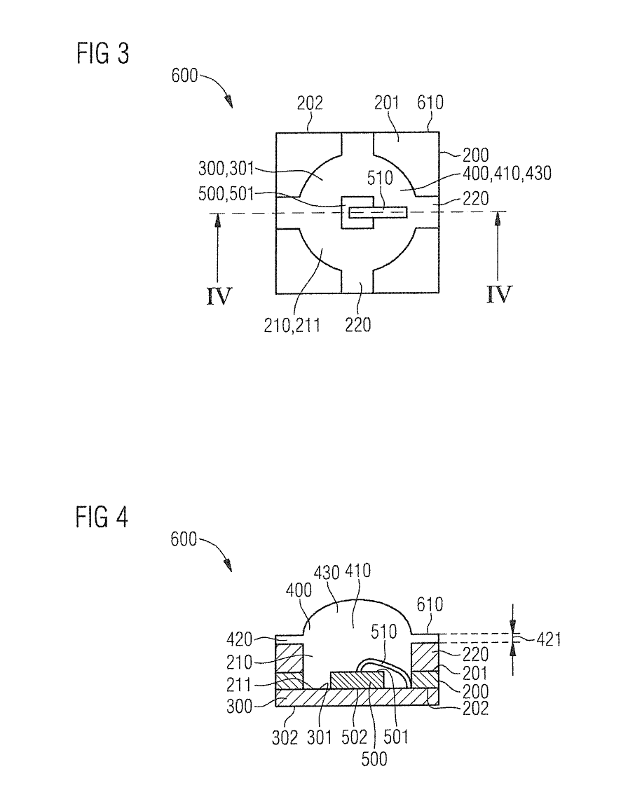

FIG. 3 shows a schematic plan view of an optoelectronic component 600 formed from a part of the divided panel 100. FIG. 4 shows a schematic sectional side view of the optoelectronic component 600. The optoelectronic component 600 has a housing 610 formed by a housing body 200 of the panel 100, a section of the lead frame 300, and the encapsulation material 400 arranged in the cavity 210 of the housing body 200 and the channels 220 of the housing body 200. The housing 610 encloses the optoelectronic semiconductor chip 500 of the optoelectronic component 600 arranged in the cavity 210 of the housing body 200.

The upper side 201 of the housing body 200 of the housing 610 of the optoelectronic component 600 has outer edges 202 formed by dividing the panel 100 along the separating planes 110. The channels 220 of the housing body 200 of the housing 610 of the optoelectronic component 600 extend from the cavity 210 of the housing body 200 to the outer edges 202 of the housing body 200.

The optoelectronic component 600 may, for example, be intended as an SMD component for surface mounting. For example, the optoelectronic component 600 may be intended for mounting by reflow soldering. To this end, two solder contact pads electrically conductively connected to the two electrical contact pads of the optoelectronic semiconductor chip 500 of the optoelectronic component 600, may be formed on the lower side 302 of the lead frame 300 of the housing 610 of the optoelectronic component 600.

It is also possible to form the housing bodies 200 arranged in the panel 100 from a ceramic material. In this case, the lead frame 300 may be omitted. Each housing body 200 of the panel 100 may have embedded electrically conductive vias extending between the bottom region 211 of the cavities 210 of the respective housing body 200 and a lower side of the housing body 200, lying opposite the upper side 201 of the respective housing body 200. The channels 220 may be configured as indentations in the substrate of the housing body 200 which may, for example, be introduced by a laser or by using multilayer ceramics. In a panel 100 of housing bodies 200 formed in this way, the rest of the structure and the further processing correspond to that described with the aid of FIGS. 1 to 4.

Our components and methods have been illustrated and described in detail with the aid of the preferred examples. Nevertheless, this disclosure is not restricted to the examples disclosed. Rather, other variants may be derived therefrom by those skilled in the art without departing from the protective scope of the disclosure.

This application claims priority of DE 10 2013 220 960.6, the subject matter of which is incorporated herein by reference.

1-15. (canceled)

16. An optoelectronic component comprising a housing body,
wherein a cavity is formed on an upper side of the housing body, and
a channel extending from the cavity to an outer edge of the upper side of the housing body is formed on the upper side of the housing body.

17. The optoelectronic component as claimed in claim 16, wherein an optoelectronic semiconductor chip is arranged on a bottom region of the cavity.

18. The optoelectronic component as claimed in claim 16, wherein an encapsulation material is arranged in the cavity and in the channel.

19. The optoelectronic component as claimed in claim 18, wherein the encapsulation material comprises silicone.

20. The optoelectronic component as claimed in claim 18, wherein the encapsulation material comprises embedded wavelength-converting particles.

21. The optoelectronic component as claimed in claim 18, wherein the encapsulation material extends over the upper side of the housing body and forms a layer there.

22. The optoelectronic component as claimed in claim 21, wherein a section arranged over the housing body of the layer has a thickness of less than 100 μm.

23. The optoelectronic component as claimed in claim 16, wherein the optoelectronic component comprises an optical lens arranged over the cavity.

24. The optoelectronic component as claimed in claim 18, wherein the optical lens is formed integrally with the encapsulation material.

25. A method of producing an optoelectronic component comprising:
providing a flat panel of a multiplicity of housing bodies, each housing body having a cavity opening onto an upper side of the panel wherein
the cavities of neighboring housing bodies connect by channels and open onto the upper side of the panel;
arranging an encapsulation material in the cavities of the housing bodies; and
dividing the panel.

26. The method as claimed in claim 25, further comprising:
arranging an optoelectronic semiconductor chip on a bottom region of the cavity of a housing body before arrangement of the encapsulation material.

27. The method as claimed in claim 25, wherein the encapsulation material flows at least partially through the channels during the arrangement of the encapsulation material.

28. The method as claimed in claim 25, wherein the encapsulation material is arranged by compression molding in the cavities.

29. The method as claimed in claim 25, wherein provision of the flat panel comprises forming the panel by injection molding.

30. The method as claimed in claim 25, wherein division of the panel is carried out along separating planes oriented perpendicularly to the channels.

31. The optoelectronic component as claimed in claim 23, wherein the optical lens is formed integrally with the encapsulation material.
